(19) United States
(12) Patent Application Publication
(10) Pub. No.: US 2024/0266793 A1
(43) Pub. Date: Aug. 8, 2024

(54) ADAPTER FOR COUPLING A BATTERY MANAGEMENT DEVICE

(71) Applicant: VARTA Microbattery GmbH, Ellwangen Jagst (DE)

(72) Inventor: Dieter Kloos, Fichtenau (DE)

(73) Assignee: VARTA Microbattery GmbH, Ellwangen Jagst (DE)

(21) Appl. No.: 18/432,715

(22) Filed: Feb. 5, 2024

(30) Foreign Application Priority Data
Feb. 7, 2023 (EP) 23155465.0

(51) Int. Cl. H01R 31/06; H01M 10/42; H01R 12/72; H01R 43/26; H02J 7/00

(52) U.S. Cl. CPC H01R 31/06; H01M 10/425; H01R 12/721; H01R 43/26; H02J 7/00032; H01M 2010/4271; H01M 2010/4278

(57) ABSTRACT

An adapter that is provided for coupling a battery management device with at least one inverter and/or battery. The adapter comprises or is a printed circuit board with at least one plug-in device for plugging the printed circuit board into the battery management device. The printed circuit board further comprises at least one plug connector, in particular an edge connector. The printed circuit board has a conductor structure that assigns interfaces for communication signals and/or control signals and/or supply voltages that are provided by the battery management device, to the matching pins of a plug connector of the at least one inverter and/or battery.

### TECHNICAL FIELD

This disclosure relates to an adapter for coupling a battery management device with at least one inverter and/or battery, preferably with a high-voltage battery, and furthermore, relates to a battery management device, a battery system and a method of coupling a battery management device to at least one inverter and/or battery.

### BACKGROUND

Batteries are used to store generated electric energy that is available but currently not required. High-voltage battery systems are particularly important in domestic or commercial environments in connection with photovoltaic systems or other regenerative energy generation devices.

Battery systems, in particular high-voltage battery systems, comprise one or more batteries that in turn each comprise a large number of rechargeable electrochemical cells. The cells are usually connected to each other in series or parallel, and within the battery system, several batteries can be connected in series and/or in parallel. Such modular systems of several batteries can be flexibly adapted to the respective requirements and conditions during installation.

To provide an alternating current, high-voltage battery systems usually comprise or are coupled with an inverter.

For the operation of the battery system, a battery management device is generally required to control and/or regulate the various parameters. A battery management device always comprises components for electronic data processing such as a microprocessor and/or a data memory. Often, a battery is equipped with electronic and/or sensor components to enable various relevant parameters to be recorded and data to be processed and/or forwarded. In many examples, the battery management device regulates the operation of the batteries of a battery system and serves to monitor and ensure its safety. Among other things, the battery management device can monitor and control the battery state of charge (SOC) and the state of health (SOH). The battery management device therefore comprises various interfaces for communication signals, control signals and/or supply voltages.

In practice, when installing a battery system and, in particular, a high-voltage battery system, components from different manufacturers are combined with each other, for example, batteries of different manufacturers. It may therefore be necessary for a battery management device to be coupled with various battery types or inverters during installation. Such different batteries and inverters usually have completely different pin assignments for the intended plug connections and work with different bus systems. In addition, batteries of different manufacturers usually each have their own data format. Therefore, complex adaptation measures are required during installation.

One option for adaptation is to provide a special battery management device for each of the various batteries or inverters. However, this requires many different hardware versions of the battery management device, one version for each design variant, and for each version a complex certification and costly warehousing is required. The more the different inverters and batteries have to be combined with each other, the more complex the situation becomes.

Another option for customization is a configurable, electronic switching matrix in the battery management device. This involves a large number of components and complex circuit implementation with correspondingly high costs. In addition, an installer must always adapt the switching matrix via the software that is time-consuming and error-prone.

Another option is to provide a separate plug option in the battery management device for each possible battery or inverter. However, this requires a relatively large number of plugs. For example, with three different inverters and three different batteries, six plugs, e.g. RJ45 sockets, would have to be provided, all of which are electrically different. In addition to the large amount of space required, the high costs for the plugs and the large housing cut-out required for the large number of sockets, this procedure also poses a great risk of confusion, as all plugs and sockets are mechanically identical but electrically different. In addition, other external devices such as a fourth type of inverter, cannot be retrofitted.

As a further option for adapting the interfaces, it is possible to implement the required functionality with a matrix of DIP switches. However, if all signals (e.g. 2×CAN: 4; RS485: 2; power: 2; error signals: 2; wake-up: 1; safety line: 1→12 signals) are to be arbitrarily switchable with two different 8-pin (16 pins) RJ45 sockets, 12×16=192 switches would be required, for example. For practical reasons, this is hardly feasible or very time-consuming.

Overall, the known procedures to assemble a battery system with different components of various manufacturers are very complex and unsatisfactory. Against this background, this disclosure is based on the task of making it easy for an installer to couple a battery management device with devices like inverters and/or batteries. The installation should be simplified such that it can be carried out with little effort for different hardware constellations and with low susceptibility to errors.

### SUMMARY

I thus provide an adapter for coupling a battery management device to at least one inverter and/or battery, characterized by the following features comprising:
a. The adapter comprises or is a printed circuit board with at least one plug-in device for plugging the printed circuit board into the battery management device;
b. the printed circuit board comprises at least one plug connector, in particular an edge connector;
c. the printed circuit board comprises a conductor structure which assigns interfaces for communication signals and/or control signals and/or supply voltages, which are provided by the battery management device, to the matching pins of a connector of the at least one inverter and/or battery.

### BRIEF DESCRIPTION OF THE DRAWINGS

FIG. 1 is a schematic circuit diagram of a high-voltage battery system using an adapter.

FIG. 2 is an example of a system configuration coded on an adapter.

FIGS. 3A and 3B show a first example of an adapter separately (A) and in the installed state (B); and

FIGS. 4A and 4B show a further example of an adapter separately (A) and in the installed state (B).

### DETAILED DESCRIPTION

My adapter is intended for coupling a battery management device with at least one inverter and/or battery. The interfaces of the various components of the system can be adapted to each other very easily with the aid of my adapter. The adapter is characterized by:
a. the adapter comprises or is a printed circuit board (PCB) which is equipped with at least one plug-in device for plugging the PCB into the battery management device;
b. the PCB comprises at least one connector, in particular an edge connector; and
c. the PCB has a conductor structure which assigns the interfaces for communication signals and/or control signals and/or supply voltages provided by the battery management device to the matching pins of a plug connector of the at least one inverter and/or battery.

As a plug-in device of the PCB according to the aforementioned feature a., every connector that is suitable to be inserted into a slot of a control device can be used. The PCB is preferably a pluggable PCB. The battery management device therefore preferably comprises a corresponding slot for the PCB.

The connector of the PCB, in particular the edge connector of the PCB, according to the aforementioned feature b. is intended for wiring to the at least one inverter and/or battery, in particular high-voltage battery. The plug connector is preferably a socket that can be connected to a corresponding plug of a connection cable of the at least one inverter or battery in a very simple manner.

It is possible for the battery management device to be adapted in a very simple way to any possible configuration with regard to the respective inverter and/or with regard to the respective battery. This facilitates, for example, the installation of a battery system comprising several batteries and/or inverters.

Since different inverters and different batteries can be provided depending on the system configuration, my adapter makes it very easy to adapt the interfaces of the battery management device to these inverters and/or batteries. This disclosure thus provides a solution for adapting and assigning data buses, signals and supply lines when coupling and installing a battery management device.

The battery itself is preferably a high-voltage battery. In other examples, two or more batteries are coupled to provide a high-voltage battery system. Each battery comprises a plurality of rechargeable electrochemical cells.

The conductor structure provided on the PCB is used to assign the interfaces, status signals, supply voltages and the like provided by the battery management device to the appropriate pins of a connector of the at least one inverter and/or battery. My adapter is therefore used to adapt the various interfaces between the battery management device and the respective at least one inverter and/or battery to each other.

The PCB is preferably preconfigured for the respective at least one inverter and/or battery. A set of different pre-configured PCBs can be available for an installer of a battery system, each of which is adapted to a specific battery and/or inverter. In this way, the installer can select the appropriate preconfigured PCB for each inverter and/or battery to be installed and plug it into the battery management device so that only the corresponding connection cable for connecting the inverter and/or battery then needs to be plugged in.

My adapter is therefore primarily concerned with adapting and linking (pinning) the interfaces of the battery management device with at least one inverter and/or battery so that, for example, the installation of a battery system can be carried out with very little effort with differently configured inverters, whereby basically only the correspondingly preconfigured PCB has to be chosen and plugged into the battery management device.

My adapter can also be used such that batteries which have different configurations can be coupled with a battery management device via an interface adaptation using the adapter. This disclosure provides a universal adaptation option for differently configured interfaces between a battery management device and devices connected thereto.

The PCB that is comprised by my adapter or which forms the adapter is preferably not intended for directly interconnecting batteries of a battery system. Preferably, the PCB generally does not comprise a high-current conduction area.

Preferably, the adapter is characterized by:
a. the PCB has a conductor structure that assigns the interfaces for communication signals and/or control signals and/or supply voltages provided by the battery management device to the appropriate pins of a plug connector of an inverter;
b. the PCB has a configuration formed by a conductor structure that assigns the interfaces for communication signals and/or control signals and/or supply voltages provided by the battery management device to the matching pins of a connector of a battery, in particular a high-voltage battery.

In some examples the PCB has either a configuration according to the aforementioned feature a. or according to the aforementioned feature b. so that the adapter is provided to adapt the interfaces of either an inverter or a (high-voltage) battery.

However, in other examples the adapter may have two or more conductor structures, each for a different type of inverter or battery. In this example, one of the conductor structures assigns the interfaces for communication signals and/or control signals and/or supply voltages provided by the battery management device to the matching pins of a connector of a first inverter or first battery and another conductor structure assigns the interfaces for communication signals and/or control signals and/or supply voltages provided by the battery management device to the matching pins of a connector of a second inverter or second battery. Another option is that one of the conductor structures assigns the interfaces for communication signals and/or control signals and/or supply voltages provided by the battery management device to the matching pins of a connector of an inverter and another conductor structure assigns the interfaces for communication signals and/or control signals and/or supply voltages provided by the battery management device to the matching pins of a connector of a battery.

Particularly preferably of the adapter, the adapter is characterized by the following additional feature:
a. the PCB comprises at least one code, in particular a hard-wired code that encodes the system configuration of the at least one inverter and/or battery, in particular the system configuration of an inverter or a high-voltage battery.

Particularly preferably, the PCB comprises a system coding so that the battery management device automatically recognizes the at least one inverter and/or battery during installation. In this example, my adapter thus fulfills the function of an interface configuration on the one hand and the function of a device recognition for the software of the battery management device on the other.

In addition, this example offers the advantage that an incorrectly selected adapter, which does not have the correct pre-configuration for the respective device, can be automatically detected and the error corrected.

Preferably the coded system configuration is the configuration of the inverter and/or battery whose interfaces are to be adapted with my adapter.

If my adapter is provided to adapt and customize the interfaces for both a specific inverter and a specific battery, it is particularly preferred that the respective adapter comprises both a coding for the system configuration of the respective inverter and a coding for the system configuration of the respective battery.

Particularly preferably examples of the adapter according to the following additional feature is provided:
a. the connector or connectors of the PCB, in particular the edge connectors, are standardized connectors, in particular RJ45 connectors.

The design of the plug connectors of the PCB as standardized plug connectors and in particular as RJ45 plug connectors (RJ—Registered Jack) is particularly advantageous, as the plug connectors of the external devices, i.e. in particular of an inverter, are usually also standardized plug connectors. Preferably, the plug connector of the PCB is a plug connector socket. RJ45 connectors in particular are so widespread that a correspondingly designed PCB can be used almost universally as an adapter with a corresponding pre-configuration for the devices available on the market. The correspondingly pre-configured adapter can therefore be used for interface adaptation when installing battery systems with, in principle, all conceivable combinations of devices available on the market.

The PCB can also be referred to as an adapter board. This adapter board is preferably designed as a double-sided PCB with edge connectors. It can be a comparatively small and pluggable PCB.

Preferably, the pluggable PCB is only equipped with the conductor tracks that make the connections for interface adaptation.

It is possible, for example, to use a PCI-E 64 edge connector card as a PCB, which is preconfigured to suit a certain inverter or battery. A PCB of this type is extremely cost-effective due to its widespread use in modern PCs. In addition, such a card or slot connector is extremely compact despite its large number of pins.

As not all pins of a PCI-E 64 connector card are required for the connection and assignment of the interfaces, there are still enough pins available to represent a system code, which the battery management device can use to recognize how the corresponding external device for which the card is intended and the system are configured. For this coding, for example, the respective pins can be connected to either +Vcc (high voltage) or GND (low voltage) to represent 1 and 0. Pins can also be left free, making trinary coding possible (one, zero, high impedance). For example, with ten pins in binary coding, 210=1024 different configurations could be coded. With a trinary coding, there would be 310=59.049 possibilities. The pins or bits of such a plug-in card, which can be used as a PCB for my adapter, can therefore also be used to code a specific hardware version of the at least one inverter and/or battery in addition to connecting and assigning the interfaces.

In further preferred examples of my adapter, at least one of the following additional features is provided:
a. the PCB comprises a further terminal, for example, a punch-down block or a pin header; and
b. the PCB is fitted with additional components.

Preferably, the aforementioned features a. and b. are realized in combination so that my adapter can provide various additional functionalities. This means that an existing system can also be subsequently expanded and supplemented with additional features and interfaces.

In particular, the PCB can carry additional components to expand the power and control electronics of a battery system.

In further examples, certain features of a battery system can be enabled or disabled by configuring the PCB as a dongle.

With regard to the number of configurations, my adapter can be designed in various ways. First of all, it is possible that the PCB is provided with a single configuration so that the adapter is designed with regard to a specific device (an inverter or a battery) to connect and assign its interfaces. In addition, it is also possible for the PCB to be preconfigured for two or more different devices. Thus, particularly preferably, in an example of my adapter, at least one of the following additional features is realized:
a. the PCB has two different conductor structures which assign the interfaces for communication signals and/or control signals and/or supply voltages, which are provided by the battery management device, to the matching pins of at least one connector of
   an inverter and/or a battery; or
   a first inverter and/or a second inverter; or
   a first battery and/or a second battery.
b. the PCB comprises two plug-in devices for plugging the PCB into the battery management device, the plug-in devices each being assigned to one of the different conductor structures;
c. the two plug-in devices are located on opposite sides of the PCB;
d. the PCB comprises a first code, in particular a hardwired code, which encodes the system configuration of an inverter, and a second code, in particular a hardwired code, which encodes the system configuration of a battery,
   or
   the PCB comprises a first code, in particular a hardwired code, which encodes the system configuration of a first inverter, and a second code, in particular a hardwired code, which encodes the system configuration of a second inverter,
   or
   the PCB comprises a first code, in particular a hardwired code, which encodes the system configuration of a first battery, and a second code, in particular a hardwired code, which encodes the system configuration of a second battery.

Preferably, the aforementioned features a. and b. and, particularly preferably, the aforementioned features a. and b. and c, and very particularly preferably, the aforementioned features a. to d. are realized in combination.

In this example, the PCB has at least two different conductor structures that represent two different configurations for two different devices, for example, for two different inverters from different manufacturers. Depending on which external device or which inverter is to be installed in the specific system, the PCB is plugged into the slot of the battery management device.

One and the same adapter can be used to adapt the interfaces of two different devices. Depending on how the PCB is plugged in, one or the other of the two different configurations is used. In this example of my adapter, either one or the other side of the PCB can be inserted into the slot of the battery management device so that the corresponding configuration for the specific device to be installed is connected. In this example, my adapter can therefore be used for different external devices, depending on requirements.

In further preferred examples of my adapter, it is also possible to combine more than two different configurations on a single PCB. Preferably, my adapter is characterized by at least one of the additional features:
a. the PCB has three or four different configurations, each of which is formed by a conductor structure that assigns the interfaces for communication signals and/or control signals and/or supply voltages provided by the battery management device to the appropriate pins of a connector of a respective device (inverter or battery);
b. the PCB comprises three or four plug-in devices for plugging the PCB into the battery management device, whereby the plug-in devices are each assigned to one of the configurations on the PCB.
c. the PCB comprises a first code, in particular a hardwired code, which encodes the system configuration of a first device (inverter or battery), and a second code, in particular a hardwired code, which encodes the system configuration of a second device (inverter or battery), and a third code, in particular a hardwired code, which encodes the system configuration of a third device (inverter or battery), and optionally a fourth code, in particular a hardwired code, which encodes the system configuration of a fourth device (inverter or battery).

Preferably, the aforementioned features a. and b., and particularly preferably, the aforementioned features a., b. and c. are realized in combination.

In these examples, the adapter is therefore to a certain extent a “triple” or “quad” version with three or four different configurations and a corresponding number of plug-in devices to insert the PCB into the slot of the battery management device. The plug-in devices are preferably located on different sides of the PCB. The respective configuration is used depending on which plug-in device is used to insert the PCB into the slot.

The external devices for which the adapter is preconfigured are preferably different inverters, for example, inverters from different manufacturers.

This disclosure also comprises a set of different PCBs or different adapters for different devices (inverters and/or batteries). These different adapters are available to the installer when installing a battery system. Depending on the specific components used for a particular installation, the installer can select the appropriate adapter or the corresponding pre-configured PCB and use it for the installation. Accordingly, this set comprises a plurality of different adapters according to the above description, whereby the adapters each have different configurations for assigning the interfaces of a battery management device to the matching pins of connectors of different devices, in particular different inverters.

This disclosure further comprises a battery management device that is equipped with at least one adapter as described above, this adapter being provided for coupling the battery management device to at least one inverter and/or (high-voltage) battery. Further, the battery management device is equipped with a connector, in particular a slot connector, for the adapter. With regard to further features of this battery management device and this adapter, reference is made to the above description.

Furthermore, this disclosure comprises a battery system and in particular a high-voltage battery system with a battery management device. The battery management device is characterized in that it is equipped with at least one adapter as described above for coupling the battery management device to an inverter and/or a battery. Further, it comprises at least one battery and/or at least one inverter. Preferably, it comprises two or more batteries and at least one inverter.

The battery system, in particular high-voltage battery system, further comprises, a plurality of rechargeable electrochemical cells. Preferably, the battery system is a modular system that is constructed from a plurality of batteries, wherein the each of the batteries comprises a plurality of rechargeable electrochemical cells. The cells may in particular be cylindrical round cells, preferably lithium-ion cells. Conveniently, these are secondary, i.e. rechargeable, lithium-ion cells.

In a battery, the electrochemical cells can be arranged and connected in battery blocks. For example, cylindrical round cells or prismatic cells can be used as electrochemical cells that are arranged in a battery block in such a way that their longitudinal axes are parallel to each other. For example, the cells can be arranged in a regular pattern in one plane within the battery block. Cylindrical round cells are particularly preferred, as the cavities that inevitably arise between the cells allow good temperature control. Two or more battery blocks of this type can be combined in a battery within a housing. A modular battery system has the particular advantage that the system can be flexibly adapted and dimensioned to the respective requirements and conditions during installation by selecting the appropriate number of batteries.

With regard to further features of this battery system and this battery management device and this adapter, reference is made to the above description.

Finally, this disclosure comprises a method of coupling a battery management device with at least one inverter and/or battery. In this method, an adapter as described above is plugged into a slot of the battery management device and a connection, in particular a cable connection, is established between a plug connector of the adapter and the at least one inverter and/or battery. When installing a battery system, for example, this method makes it very easy for the installer to adapt the interface between the battery management device and the at least one inverter and/or battery via the preconfigured pluggable PCB. With regard to further features of this method, reference is also made to the above description.

The particular advantage of this disclosure is that my adapter allows very simple coupling and interface adaptation when installing a system with a battery management device. After the mechanical installation of the system at the end customer's premises, the installer first connects the data connections with standard patch cables, for example, and then plugs the adapter suitable for the respective system into the battery management device. The interfaces for the at least one inverter and/or battery are then configured and the software of the battery management device is informed about which device, for example, which inverter, is connected.

My adapter also allows a very cost-effective solution to the problem of interface adaptation. The plug-in cards for my adapters can be based on mass-produced products, whereby only a corresponding configuration of the plug-in cards has to be carried out in adaptation to the interfaces of the respective devices. The installer can therefore prepare various preconfigured adapters in a very cost-effective manner that can be used for different inverter versions when installing a battery system, for example. For particularly preferred configurations, such adapters can also be included with every control computer supplied, in particular every battery management device supplied, or every battery supplied.

For manufacturers of battery systems and battery management devices, it is not necessary to keep different product variants in stock. It is always possible to adapt inverters or batteries from different manufacturers by plugging in the corresponding preconfigured adapter.

After all, this disclosure offers considerable error-proofing. The only error in the configuration that can still be made by the installer is plugging in the wrong adapter. This can be easily prevented, for example, by clearly labeling the adapter. In addition, in the preferred example of the adapter with system coding, this error is detected in good time by the software of the battery management device during installation in the course of system recognition so that such an error can be corrected quickly.

My adapter is particularly useful when installing domestic energy storage systems. In principle, the system with my adapter can also be used with other types of devices and systems. In general, my adapter is very well suited for a flexible and easy-to-perform interface adaptation of various components of a system.

Further features and advantages are shown in the following description of preferred example in conjunction with the drawings. The disclosed features can be realized individually or in combination with each other.

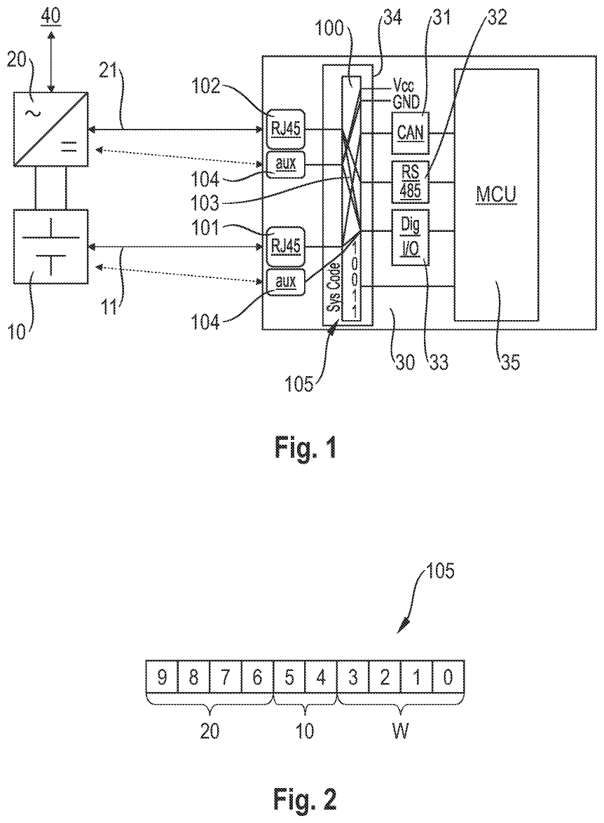

FIG. 1 schematically illustrates the structure of a high-voltage battery system comprising a high-voltage battery 10, an inverter 20 and a battery management device 30 that is the control device for the entire system. A direct current provided by the battery 10 can be converted into an alternating current by the inverter 20 so that it can be supplied to a power grid 40. Conversely, the battery 10 can be charged with an alternating current from grid 40 via the inverter 20. The battery 10 and the inverter 20 are controlled via the battery management device 30 and can communicate via the battery management device 30. For this purpose, cablings 11 and 21 are provided between the battery system 10, the inverter 20 and the battery management device 30.

To adapt the various interfaces 31, 32, 33 to the corresponding interfaces of the battery system 10 and the inverter 20, an adapter 100 is inserted into a corresponding slot 34 of the battery management device 30. My adapter 100 is in the form of a preconfigured PCB that ensures that the correct pin assignment is made for the plug connections 101, 102 and thus for the cabling with the battery 10 and the inverter 20. This adaptation of the interfaces via the adapter 100 is carried out in this example both for the battery system 10 and for the inverter 20. In other examples, the interconnection of the battery management device with the battery is carried out differently and only the connection to the inverter is adapted.

The connectors 101 and 102 of the adapter 100 are preferably standard connectors. The very widely used RJ45 connectors are particularly preferred here. In this example, the adapter 100 provides two edge connectors in the form of RJ45 connector sockets. The external devices, i.e. the battery system 10 and the inverter 20, preferably also have RJ45 connectors so that simple cabling is possible without further adaptations.

The interfaces are adapted via a preconfigured conductor structure 103 on the PCB. This conductor structure 103 is used to assign the interfaces 31, 32 and 33 of the battery management device 30 shown here to the matching pins of the connectors of the battery 10 and the inverter 20 so that communication between the processor 35, for example, a microprocessor, and the battery system 10 and the inverter 20 and a control of the battery system 10 and the inverter 20 is possible.

In addition, the adapter 100 can also be used to adapt the connection to other signal outputs and inputs 104 (aux).

In this example, a coding of the configuration of the battery system 10 and the inverter 20 is provided on the adapter 100 in the form of a hard-wired code 105. FIG. 2 shows an exemplary assignment of the pins of a PCI-E 64 connector card that can be used as the adapter 100. In this example of the coding 105, the pins 9, 8, 7 and 6 code the inverter 20, the pins 5 and 4 code the high-voltage battery system 10 and the pins 3, 2, 1 and 0 code the hardware version (HW) used and possibly other features of the system. Based on this coding, the software of the battery management device 30 can recognize how the entire system is configured and which individual components are to be connected. For this coding, the respective pins are preferably connected to +Vcc or GND to represent a binary code. In other examples, a trinary code (one, zero, high-impedance) can also be represented with this.

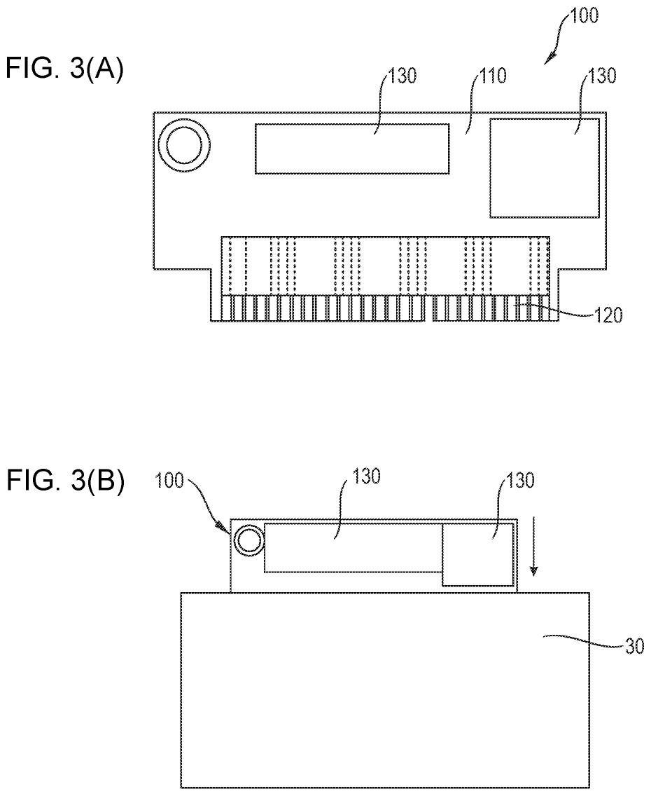

FIGS. 3A and 3B show an example of an adapter 100 in the form of a PCB 110 that is provided on one longitudinal side with a plug-in device 120, via which the adapter 100 can be installed in a corresponding slot of a battery management device 30. FIG. 3A shows the separate PCB 110 and FIG. 3B shows the installed state of the PCB or the adapter 100 in the battery management device 30. The PCB is also equipped with one or more plug connectors, in particular edge connectors that are not shown in detail here and can be attached directly to the PCB or can be connected to the PCB 110 via corresponding cable connections. In particular, these are RJ45 connector sockets.

The adapter 100 is preconfigured for an interface adaptation between an inverter or a battery and the battery management device 30 via corresponding conductor structures that are not shown in detail here.

The example of an adapter 100 shown here is provided with two labeling fields 130 that can contain various information for the user in written form, in particular information on the system configuration and on the designations of the inverter and/or battery whose circuitry is to be adapted hereby, e.g. a serial number or the like.

Furthermore, a circular hole is provided at the top left of the illustration in FIG. 3A so that several such adapters can be combined with a ring or similar to form a kind of bundle and are available to the installer in a handy manner. The installer then has various possible configurations to hand, so to speak, and can select and install the right adapter for the respective system in just a few simple steps.

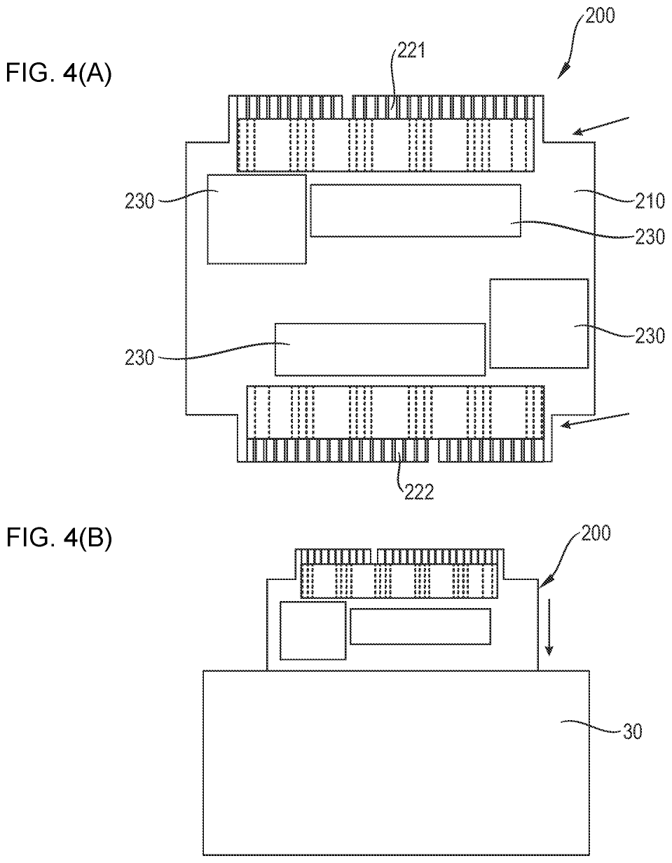

FIGS. 4A and 4B illustrate a dual version of an adapter 200, wherein two different conductor structures are provided on the PCB 210. FIG. 4A shows the separate PCB 210 and FIG. 4B shows the installed state of the PCB or the adapter 200 in the battery management device 30. Such an adapter 200 can be optionally used for adapting the interfaces for two different inverters or batteries. For this purpose, the adapter 200 comprises two plug-in devices 221, 222 on opposite longitudinal sides of the PCB 210. When the PCB 210 is inserted into the slot of a power management device 30 via the plug-in device 221, those conductor structures of the adapter 200 that adapt the interfaces for a first device, for example, a first inverter, come into play. If the adapter 200 is installed in the slot of the battery management device 30 via the plug-in device 222, those conductor structures on the PCB 210 that adapt the interfaces for a second device, for example, a second inverter, come into play. Depending on the device used, for example, an inverter from manufacturer A or an inverter from manufacturer B, one side or the other of the PCB 210 can be inserted into the slot of the battery management device 30 to connect the interfaces correctly.

The adapter 200 has labeling fields 230 to provide the necessary data and information for the installer so that the correct insertion of the adapter 200 or the selection of the correct side of the adapter 200 is ensured.

For the installation of a battery system, the installer has various adapters at his disposal, each of which is preconfigured for different device. In this way, the installer can select the correct adapter (and/or the correct adapter side, if applicable) to suit the external devices to be installed and install them in the slot of the battery management device.

My adapter allows the various hardware components of a system to be adapted by plugging in a single, small and very cost-effective PCB or plug-in card. In addition, this provides a universal solution to the problem of interface adaptation when coupling different devices. This interface adaptation is also suitable for later adaptations to an already installed system.

What is claimed is:

1. An adapter for coupling a battery management device to at least one inverter and/or battery, comprising:
a. a printed circuit board with at least one plug-in device for plugging the printed circuit board into the battery management device;
b. the printed circuit board comprises at least one plug connector;
c. a conductor structure which assigns interfaces for communication signals and/or control signals and/or supply voltages, which are provided by the battery management device, to the matching pins of a connector of the at least one inverter and/or battery.

2. The adapter according to claim 1, wherein the battery is a high-voltage battery.

3. The adapter according to claim 1, wherein the printed circuit board comprises at least one code which encodes the system configuration of the at least one inverter and/or battery.

4. The adapter according to claim 1, wherein the connector or connectors of the printed circuit board are RJ45 connectors.

5. The adapter according to claim 1, wherein:
a. the printed circuit board has two different conductor structures which assign the interfaces for communication signals and/or control signals and/or supply voltages, which are provided by the battery management device, to the matching pins of at least one connector of
an inverter and/or a battery; or
a first inverter and/or a second inverter; or
a first battery and/or a second battery;
b. the printed circuit board comprises two plug-in devices for plugging the printed circuit board into the battery management device, the plug-in devices each being assigned to one of the different conductor structures;
c. the two plug-in devices are located on opposite sides of the printed circuit board; or
d. the printed circuit board comprises a first code which encodes the system configuration of the inverter, and a second code which encodes the system configuration of the battery,
or
the printed circuit board comprises a first code which encodes the system configuration of a first inverter, and a second code which encodes the system configuration of a second inverter,
or
the printed circuit board comprises a first code which encodes the system configuration of a first battery, and a second code which encodes the system configuration of a second battery.

6. A set comprising a plurality of adapters according to claim 1, characterized in that the adapters each have a different configuration for assigning the interfaces of the battery management device to the matching pins of plug connectors of different inverters and/or batteries.

7. A battery management device, equipped with at least one adapter according to claim 1, for coupling the battery management device to the at least one inverter and/or a battery.

8. A battery system having a battery management device, according to claim 7.

9. A method of coupling a battery management device to at least one inverter and/or battery, characterized in that the adapter according to claim 1 is plugged into a slot of the battery management device and a connection is established between the plug connector of the adapter and the at least one inverter and/or battery.
